(19) United States
(12) Patent Application Publication
(10) Pub. No.: US 2025/0279297 A1
(43) Pub. Date: Sep. 4, 2025

(54) VARIABLE VENT PRESSURE AND FLOW FOR FLUSHING LOADLOCK CHAMBER

(71) Applicant: Axcelis Technologies, Inc., Beverly, MA (US)

(72) Inventors: John F. Baggett, Amesbury, MA (US); Vincent Szeto, Newton, MA (US)

(21) Appl. No.: 19/063,876

(22) Filed: Feb. 26, 2025

Related U.S. Application Data
(60) Provisional application No. 63/559,229, filed on Feb. 29, 2024.

(51) Int. Cl. H01L 21/67

(52) U.S. Cl. CPC H01L 21/67201

(57) ABSTRACT

A workpiece processing system has a process chamber for processing a workpiece. A loadlock chamber has a workpiece support to support the workpiece. A vacuum isolation valve permits the workpiece to transfer between the workpiece support and the process environment. An atmospheric isolation valve permits the workpiece to transfer between the workpiece support and an atmospheric environment. A vent gas control device controls a pressure or a flow rate of a vent gas to the loadlock volume. A workpiece location system determines a presence of the workpiece on the workpiece support. The vent gas control device is controlled based on the workpiece being present on the workpiece support, the process time, and the vent time, maximizing the pressure or flow rate of the vent gas when the workpiece is not on the workpiece support, and maximizing conditioning of the loadlock chamber.

### REFERENCE TO RELATED APPLICATIONS

This application claims the benefit of U.S. Provisional Application Ser. No. 63/559,229 filed Feb. 29, 2024, entitled, “VARIABLE VENT PRESSURE AND FLOW FOR FLUSHING LOADLOCK CHAMBER”, the contents of which are herein incorporated by reference in their entirety.

### FIELD

The present disclosure relates generally to workpiece processing systems and methods for processing workpieces, and more specifically to a system, apparatus, and method for conditioning a loadlock chamber used in ion implantation.

### BACKGROUND

In semiconductor processing, many operations may be performed on a single workpiece or semiconductor wafer. In general, each processing operation on a workpiece is typically performed in a particular order, wherein each operation waits until completion of a preceding operation, thus affecting the time at which the workpiece will become available for a subsequent processing step. Tool productivity or throughput for relatively short processes performed under vacuum, such as ion implantation, can be severely limited if the process flow leading to the processing location is interrupted by sequential events associated with such processing. For example, operations such as an exchange of workpieces between transport carriers or storage cassettes and the processing system, a transfer of the workpiece from an atmospheric environment into an evacuated environment of an implantation chamber of the processing system, and an orientation of the workpiece (e.g., notch alignment) within the evacuated environment, can have a significant impact on tool productivity.

Processing of a workpiece, such as ion implantation, for example, is typically performed at a reduced pressure within an implantation chamber, wherein ions are generally accelerated along a beam line, and wherein the ions enter the evacuated implantation chamber and strike the workpiece in a predetermined manner. Several operations are typically performed leading up to the implantation in order to introduce the workpiece into the implantation chamber, as well as to properly position and orient the workpiece with respect to the ion beam within the ion implantation chamber. For example, the workpiece is transferred via a robot from an atmospheric cassette or storage device into a loadlock chamber, wherein the loadlock chamber is subsequently evacuated in order to bring the workpiece into the processing environment of the ion implanter. The cassette or storage device, for example, may be delivered to the ion implanter via a conveyor system or other type of delivery.

U.S. Pat. No. 5,486,080 to Sieradzki, for example, details a system for transferring wafers for vacuum processing. The system employs two wafer transport robots for moving wafers from two load locks past a processing station. Additional patents relating to serial end stations are U.S. Pat. Nos. 6,350,097, 6,555,825, and 5,003,183. Further, commonly-owned U.S. Pat. No. 7,010,388 to Mitchell et al. details a wafer handling system for handling one or two wafers at a time.

### SUMMARY

The present disclosure overcomes the limitations of the prior art by providing a system, apparatus, and method for conditioning a loadlock chamber while maximizing throughput and minimizing costs of ownership associated therewith. More particularly, the present disclosure provides a system and method for optimizing particle contamination concerns in light of workpiece throughput.

Accordingly, the following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

According to one example aspect of the disclosure, a workpiece processing system is provided, wherein a process chamber is configured for processing a workpiece within a process environment at a vacuum pressure, whereby processing the workpiece defines a process time. A loadlock chamber further defines a loadlock volume therein, wherein the loadlock chamber comprises a workpiece support configured to selectively support the workpiece within the loadlock volume.

A vacuum isolation valve, for example, is configured to provide selective fluid communication between the loadlock volume and the process environment. The vacuum isolation valve is further configured to selectively permit the workpiece to transfer between a loadlock position within the loadlock volume and the process environment.

An atmospheric isolation valve, for example, is configured to provide selective fluid communication between the loadlock volume and an atmospheric environment at an atmospheric pressure. The atmospheric isolation valve is further configured to selectively permit the workpiece to transfer between the loadlock position and the atmospheric environment.

A vent gas control device, for example, is configured to selectively control one or more of a pressure and a flow rate of a vent gas from a vent gas source to the loadlock volume, wherein a vent time is defined by a change from the vacuum pressure to the atmospheric pressure within the loadlock volume. A workpiece location system is further provided and configured to determine a presence of the workpiece on the workpiece support within the loadlock volume.

A controller, for example, is further provided and configured to control the vent gas control device based, at least in part, on the presence of the workpiece on the workpiece support, the process time, and the vent time. The controller, for example, is configured to maximize the one or more of the pressure and the flow rate of the vent gas from the vent gas source to the loadlock chamber when the workpiece is not present on the workpiece support, thereby maximizing a conditioning of the loadlock chamber.

In accordance with one example, a pressure monitor is configured to measure a loadlock pressure within the loadlock volume, wherein the controller is further configured to control the vent gas control device based on the loadlock pressure.

In another example, the controller is further configured to control the vent gas control device based on a plurality of process parameters associated with the process chamber and the loadlock chamber. The plurality of process parameters, for example, can comprise one or more of a process recipe associated with processing the workpiece within the process environment and a characterization of the loadlock chamber, wherein the characterization of the loadlock chamber defines a minimum vent time. The controller, for example, can be configured to maximize the flow rate concurrent with the change from the vacuum pressure to the atmospheric pressure.

The workpiece processing system, for example, can further comprise an ion implantation system configured to process the workpiece by directing an ion beam toward the workpiece within the process chamber.

In another example, a vacuum control device is configured to selectively evacuate the loadlock volume and to control the vacuum pressure from a vacuum source to the loadlock volume, wherein a vacuum time is defined by a change from the atmospheric pressure to the vacuum pressure within the loadlock volume.

The workpiece location system, for example, can comprise a workpiece sensor configured to sense the workpiece on the workpiece support and to provide feedback to the controller. The workpiece sensor, for example, can comprise one or more of an optical sensor and a proximity sensor configured to detect the workpiece when the workpiece is present on the workpiece support. In another example, the controller is further configured determine the presence of the workpiece on the workpiece support.

The vent gas control device, for example, can comprise one of a mass flow controller, a pressure flow controller, a pressure regulator, a velocity regulator, and a needle valve.

In accordance with another example aspect of the disclosure, a workpiece processing system is provided having a process chamber configured for processing a workpiece within a process environment at a vacuum pressure. A loadlock chamber defines a loadlock volume and has a workpiece support disposed therein, wherein the workpiece support is configured to selectively support the workpiece in a loadlock environment. The loadlock chamber is configured to selectively isolate the process environment from an atmospheric environment at atmospheric pressure.

A vent gas control device, for example, is configured to selectively control one or more of a pressure and a flow rate of a vent gas from a vent gas source to the loadlock volume, wherein a vent time is defined by a change from the vacuum pressure to the atmospheric pressure within the loadlock volume. The vent gas control device can comprise one of a mass flow controller, a pressure flow controller, a pressure regulator, a velocity regulator, a needle valve. Further, a workpiece location system is configured to determine a presence of the workpiece on the workpiece support within the loadlock volume.

A controller, for example, is configured to control the vent gas control device based, at least in part, on the presence of the workpiece on the workpiece support. The controller can be configured to maximize the one or more of the pressure and the flow rate of the vent gas from the vent gas source to the loadlock chamber within the vent time when the workpiece is not present on the workpiece support, thereby maximizing a conditioning of the loadlock chamber.

The loadlock chamber, for example, can comprise a vacuum isolation valve configured to provide selective fluid communication between the loadlock volume and the process environment, wherein the vacuum isolation valve is further configured to selectively permit the workpiece to transfer between the workpiece support and the process environment. The loadlock chamber can further comprise an atmospheric isolation valve configured to provide selective fluid communication between the loadlock volume and the atmospheric environment, wherein the atmospheric isolation valve is further configured to selectively permit the workpiece to transfer between the workpiece support and the atmospheric environment.

In one example, processing of the workpiece within the process chamber defines a process time, wherein the controller is further configured to control the vent gas control device based on the process time.

In another example, a pressure monitor is configured to measure a loadlock pressure within the loadlock volume, wherein the controller is further configured to control the vent gas control device based on the loadlock pressure. The controller can be further configured to control the vent gas control device based on a plurality of process parameters associated with the process chamber and the loadlock chamber. The plurality of process parameters can comprise one or more of a process recipe associated with processing the workpiece within the process environment and a characterization of the loadlock chamber, wherein the characterization of the loadlock chamber defines a minimum vent time.

The workpiece location system, for example, can comprise a workpiece sensor configured to sense the workpiece on the workpiece support and to provide feedback to the controller. The workpiece sensor can comprise one or more of an optical sensor and a proximity sensor configured to detect the workpiece when the workpiece is present on the workpiece support.

In accordance with another example aspect of the disclosure, a method is provided for conditioning a loadlock chamber in a workpiece processing system. The method comprises identifying parallel processes in the workpiece processing system, thereby defining a critical path associated with processing a workpiece. A process time is determined based on process parameters associated with the workpiece processing system, and a presence of the workpiece in the loadlock chamber is determined. Further it is determined whether a venting of the loadlock chamber is in the critical path.

According to one example, a throughput of the workpiece through the workpiece processing system is maximized if the workpiece is present in the loadlock chamber or if the venting of the loadlock chamber is in the critical path. Further, in another example, one or more of a vent pressure and a flow rate of a vent gas to the loadlock chamber is maximized when the workpiece is not present in the loadlock chamber. The one or more of the vent pressure and the flow rate, for example, are maximized based on the process parameters, thereby maximizing a conditioning of the loadlock chamber.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 illustrates a block diagram of a workpiece processing system in accordance with various example aspects of the present disclosure.

FIG. 2 is a schematic representation of a vent system for a loadlock chamber in accordance with various example aspects of the present disclosure.

FIG. 3 is a block diagram illustrating an exemplary method for optimizing conditioning of a loadlock chamber and reducing particle contamination according to another example aspect of the disclosure.

FIG. 4 is a block diagram illustrating a control system configured to control a workpiece processing system in accordance with another example aspect.

### DETAILED DESCRIPTION

The present disclosure is directed generally toward semiconductor processing systems and methods, and more particularly, to a system for controlling a conditioning of a loadlock chamber for the semiconductor processing system, whereby particle contamination and throughput are optimized based on a critical path of a process flow for the semiconductor processing system.

Accordingly, the present disclosure will now be described with reference to the drawings, wherein like reference numerals may be used to refer to like elements throughout. It should be understood that the description of these aspects are merely illustrative and that they should not be interpreted in a limiting sense. In the following description, for purposes of explanation, numerous specific details are set forth in order to provide a thorough understanding of the present disclosure. It will be evident to one skilled in the art, however, that the present disclosure may be practiced without these specific details.

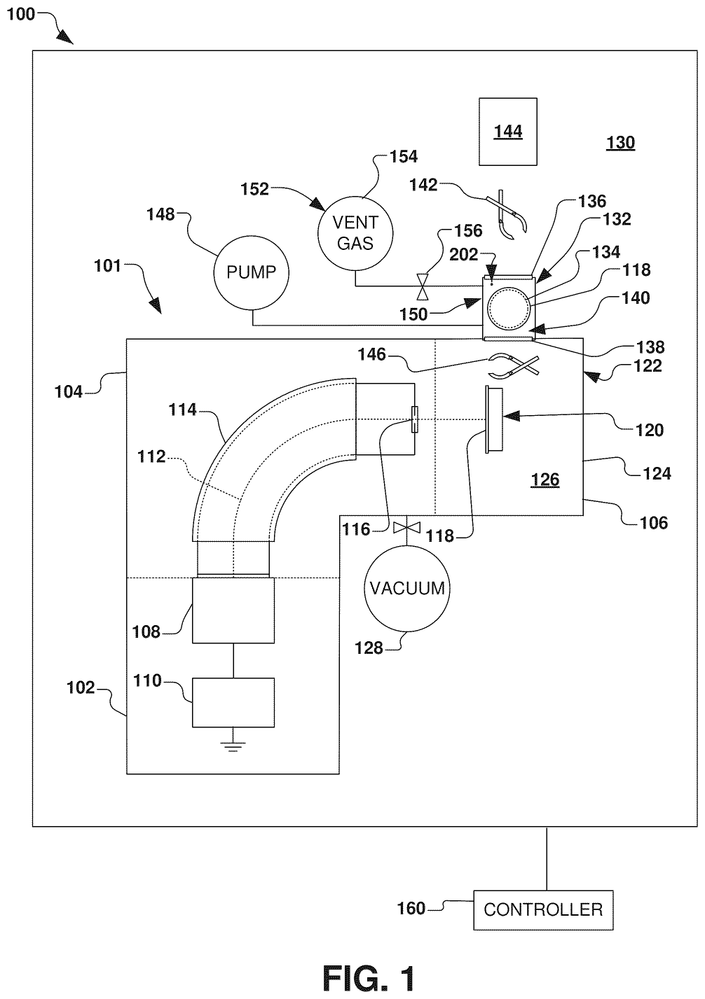

In order to gain a broader understanding of the invention and in accordance with various aspects of the present disclosure, FIG. 1 illustrates an example of a workpiece processing system 100. While the workpiece processing system 100 in the present example comprises an exemplified ion implantation system 101, it will be appreciated that various other types of vacuum-based semiconductor processing systems are also contemplated, such as for example, plasma processing systems, or other semiconductor processing systems. The ion implantation system 101, for example, comprises a terminal 102, a beamline assembly 104, and an end station 106.

Generally speaking, an ion source 108 in the terminal 102 is coupled to a power supply 110 to ionize a dopant gas into a plurality of ions and to form an ion beam 112. The ion beam 112 in the present example is directed through a mass analysis apparatus 114, and out an aperture 116 towards the end station 106. In the end station 106, the ion beam 112 bombards a workpiece 118 (e.g., a substrate such as a semiconductor wafer, a display panel, etc.), which is selectively clamped or mounted to a workpiece chuck 120. The workpiece chuck 120, for example, may comprise an electrostatic chuck (ESC), a thermal chuck, a mechanical clamp, or other workpiece support, wherein the workpiece chuck is configured to selectively support the workpiece 118 in the end station 106.

Once embedded into the lattice of the workpiece 118, the implanted ions change the physical and/or chemical properties of the workpiece. Because of this, ion implantation is used in semiconductor device fabrication and in metal finishing, as well as various applications in materials science research.

The ion beam 112 of the present disclosure can take any form, such as a pencil or spot beam, a ribbon beam, a scanned beam, or any other form in which ions are directed toward end station 106, and all such forms are contemplated as falling within the scope of the disclosure.

According to one exemplified aspect, the end station 106 comprises a process chamber 122, such as a vacuum chamber 124, wherein a process environment 126 is associated with the process chamber. The process environment 126 (e.g., a high vacuum environment) generally exists within the process chamber 122, and in one example, comprises a vacuum produced by a vacuum source 128 (e.g., a vacuum pump) coupled to the process chamber and configured to substantially evacuate the process chamber.

In order to transfer workpieces 118 between an atmospheric environment 130 at atmospheric pressure and the process environment 126 of the process chamber 122, a loadlock chamber 132 is operably coupled to the process chamber. The loadlock chamber 132, for example, comprises a workpiece support 134 configured to selectively support the workpiece 118 within the loadlock chamber. The present disclosure contemplates any number of loadlock chambers 132 operably coupled to the process chamber 122, any of the loadlock chambers may be further configured as a dual loadlock chamber (not shown), such that two workpieces 118 may be individually or collectively supported within, loaded into, or unloaded from the dual loadlock chamber, as will be appreciated by one of ordinary skill in the art.

The loadlock chamber 132, for example, comprises an atmospheric loadlock valve 136 (e.g., also called an atmospheric loadlock door) and a vacuum loadlock valve 138 (e.g., also called a vacuum loadlock door). The atmospheric loadlock valve 136 and the vacuum loadlock valve 138, for example, are configured to selectively isolate a loadlock environment 140 within the loadlock chamber 132 from the respective atmospheric environment 130 and the process environment 126. The atmospheric loadlock valve 136, for example, is further configured to selectively permit a transfer of the workpiece 118 between the workpiece support 134 within the loadlock chamber 132 and the atmospheric environment 130 external to the loadlock chamber. For example, an atmospheric workpiece transfer apparatus 142 can be configured to transfer the workpiece 118 from the workpiece support 134 to a workpiece carrier 144 (e.g., a front opening unified pod or FOUP) in the atmospheric environment.

The vacuum loadlock valve 138, for example, is further configured to selectively permit a transfer of the workpiece 118 between the workpiece support 134 and the process environment 126, such as to and from the workpiece chuck 120, and via a vacuum workpiece transfer apparatus 146. One or more of the atmospheric workpiece transfer apparatus 142 and the vacuum workpiece transfer apparatus 146, for example, may comprise one or more transfer robots.

In accordance with one example, a loadlock pump 148 is provided in selective fluid communication with the loadlock chamber 132, whereby the loadlock pump is configured to selectively evacuate a loadlock volume 150 defined within the loadlock chamber 132. The loadlock pump 148 for example, is configured to selectively evacuate the loadlock volume 150 and to lower a pressure associated with the loadlock environment 140 from atmospheric pressure associated with the atmospheric environment 130 to the vacuum pressure associated with the process environment 126 when the atmospheric loadlock valve 136 and the vacuum loadlock valve 138 are closed. Once the pressure within the loadlock environment 140 is at approximately the same pressure as the vacuum environment, the vacuum loadlock valve 138 may be opened for transfer of the workpiece 118 to the process environment 126.

Further, in accordance with the present disclosure, a vent gas supply system 152 is provided. The vent gas supply system 152, for example, comprises a vent gas source 154 configured to selectively deliver a vent gas, such as pressurized nitrogen gas, to the loadlock volume 150. The vent gas supply system 152, for example, further comprises a vent gas control device 156 in selective fluid communication with the vent gas source 154 and the loadlock volume 150, whereby the vent gas control device is configured to control one more of a pressure, a flow rate, and a velocity of the vent gas, as will be discussed in greater detail infra. The vent gas control device 156, for example, can comprise a mass flow controller, a pressure flow controller, a pressure regulator, a velocity regulator, a needle valve, or the like.

In accordance with another exemplified aspect, a controller 160 is further operably coupled to the workpiece processing system 100, and configured to provide control of one or more of the components within the workpiece processing system. The controller 160, for example, can be configured to provide overall control of the ion implantation system 101. The controller 160, for example, can further provide control of the loadlock chamber 132, the loadlock pump 148, and the vent gas supply system 152. Accordingly, the controller 160 can be configured to control various aspects of the ion implantation system 101 in order to implant ions into the workpiece 118, transfer workpieces between the atmospheric environment and the process environment, and to further control a timing, thereof.

The present disclosure appreciates that the workpiece processing system 100 can comprise various semiconductor processing systems configured to perform various process on various types of workpieces 118, whereby the loadlock chamber 132 can be utilized for transferring the workpiece between the process environment 126 and the atmospheric environment 130. In one example, the workpiece 118 is loaded in the loadlock chamber 132 from the atmospheric environment 130, and the loadlock chamber is evacuated or otherwise pumped down from atmospheric pressure to a vacuum pressure associated with the process environment 126 via the loadlock pump 148. The workpiece 118 is then removed from the loadlock chamber 132 and transferred to the process chamber 122 via the vacuum workpiece transfer apparatus 146 (e.g., one or more robots), whereby the workpiece undergoes semiconductor processing (e.g., ion implantation) in the process chamber. The workpiece 118 can be transferred back to loadlock chamber 132 after processing, whereby the loadlock chamber is subsequently vented via the vent gas supply system 152 in order to return the loadlock chamber to atmospheric pressure for removal of the processed workpiece and be readied for subsequent workpieces in order to repeat the process.

Accordingly, in some instances, the loadlock chamber 132 can be considered to be in a so-called “critical path” of workpiece processing, whereby throughput of workpieces 118 through the workpiece processing system 100 can be affected by the time taken for the evacuation and venting of the loadlock chamber. A process that is in the critical path, for example, is considered to be a process that impacts a total time for the process to complete. For example, when processes are performed in parallel, the process that is in the critical path is typically the process that takes the longest to perform.

The loadlock chamber 132, for example, can comprise a dual-workpiece loadlock chamber (not shown), for example, in order to increase throughput of workpieces 118, whereby two workpieces can be transferred into and out of the dual-workpiece loadlock chamber in order to provide various efficiencies, thus possibly removing the transfer of workpieces between the atmospheric environment 130 and the process environment 126 from the critical path of workpiece processing. Further, multiple loadlock chambers (not shown) can be utilized to provide additional throughput efficiencies, such that one loadlock chamber may be vented while another loadlock chamber is evacuated, or vice-versa in order increase throughput and potentially remove the transfer from the critical path.

In semiconductor processing that incorporates ion implantation, for example, various configurations of ion implantation system 101 can be utilized, such as configurations for performing high-current implants, high-energy implants, or other implants having various so-called process recipes associated with various implant conditions, whereby a time taken by the actual ion implantation into the workpiece 118 in the process chamber 122 can vary based on the particular type of implant or process recipe selected. As such, the present disclosure appreciates that the particular semiconductor process being performed on the workpiece can thus also be in the critical path.

For example, a particular ion implantation into one workpiece 118 can be performed in parallel with the evacuation or venting of the loadlock chamber 132 associated with the transfer of another workpiece between the atmospheric environment 130 and the process environment 126. Accordingly, either of the processing of workpieces 118 in the process chamber 122 or the evacuation or venting of the loadlock chamber 132 can be in the critical path, depending on the particular semiconductor processing being performed on the workpieces.

For high energy implants, for example, the evacuation or venting of the loadlock chamber 132 can be in the critical path due to the relatively fast process of implanting high energy ions into the workpiece 118. As such, a time taken for the high energy ion implantation process can be less than a time taken for the transfer of workpieces via the loadlock chamber 132 between the atmospheric environment 130 and the process environment 126. For high current implants, on the other hand, the ion implantation, itself, can be in the critical path due, at least in part, to the high current and high dosage of ions implanted into the workpiece 118. In such a high current implant, a time taken for the high current ion implantation process can be substantially longer than a time taken for the transfer of workpieces 118 between the atmospheric environment 130 and the process environment 126.

While implantation times can vary from several seconds to several minutes based on the type of implantation and/or process recipe, conventional ion implantation systems are not known to vary the time or pressure for venting the loadlock chamber 132 based on the respective time for ion implantation into the respective workpieces 118. Conventionally, the focus of maximizing throughput has centered on removing any transportation of the workpiece between the atmospheric environment and the process environment from the critical path, while also maintaining low pressures or flow rates during vent routines to minimize particle contamination.

Reducing pressures during a vent routine of the loadlock chamber 132 when the workpiece 118 is present within the loadlock chamber can improve particle performance of the ion implantation system 101. By minimizing the momentum of flow through the loadlock chamber 132 when the workpiece 118 is present in the loadlock chamber, existing particles present within the loadlock chamber (or on the workpiece) are not disturbed, and/or new particles are not created within the loadlock chamber due to the minimized flow through the loadlock chamber.

Increasing pressures during the vent routine of the loadlock chamber 132 can disrupt or dislodge particles already contained in the loadlock chamber, thus allowing them to be pumped away, and increasing a so-called “conditioning” effect of the pump and purge cycle. It is desirable to condition the loadlock chamber 132 to improve particle performance of the loadlock chamber when no workpieces 118 are being cycled through the loadlock chamber, whereby increased particle performance (e.g., decreased particle contamination on workpieces) of the ion implantation system 101 is the desired result.

Loadlock chamber conditioning has been previously performed only at times when no production workpieces are being processed, such as during auto-tuning of an ion implantation system, or when the processing system is otherwise idle and not processing workpieces therethrough, whereby such conditioning requiring no workpiece to be present within the system can cause delays or efficiency losses in the total number of workpieces processed in a given day.

The present disclosure advantageously provides conditioning of the loadlock chamber 132, even when workpieces 118 are present within the ion implantation system 101, by advantageously sensing a presence of the workpiece within the loadlock chamber or elsewhere within the ion implantation system 101. For example, one workpiece 118 may be removed from the loadlock chamber 132 for implantation processing in the process environment 126, and while the workpiece is being processed in the process chamber 122, venting of the loadlock chamber can be performed in parallel to receive another workpiece from the atmospheric environment for processing. The present disclosure appreciates that the loadlock chamber 132 can be advantageously vented from the vacuum pressure associated with the process environment 126 to atmospheric pressure associated with the atmospheric environment 130, such that the pressure and/or flow rate of venting of the loadlock chamber can be increased while still not being in the critical path of the process.

The disclosure further presently appreciates that the fast venting of the loadlock chamber 132 can be disruptive or disturbing to particles that may be present within the loadlock chamber. For example, a high-pressure vent gas (e.g., pressurized nitrogen gas) is flowed into the loadlock chamber 132 to quickly vent the loadlock chamber to atmospheric pressure. Such a high-pressure vent gas can have a conditioning effect on the loadlock chamber 132, however, as contaminant particles that may be present within the loadlock chamber can be disrupted and removed from the loadlock chamber during subsequent pumping.

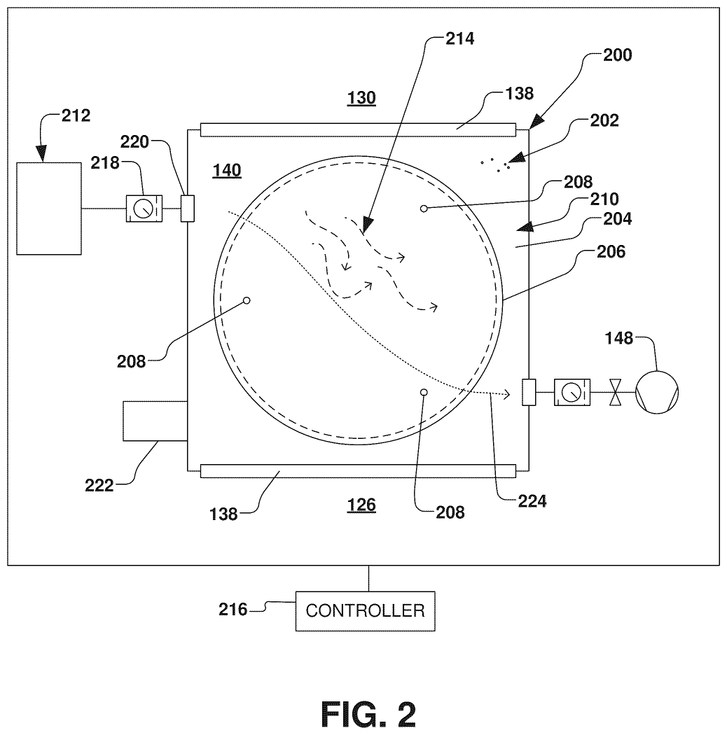

Accordingly, FIG. 2 illustrates a loadlock chamber 200 in accordance with various example aspects of the present disclosure, whereby conditioning of the loadlock chamber 200 can be advantageously attained. The loadlock chamber 132 of FIG. 1, for example, may comprise various features of the loadlock chamber 200 shown in FIG. 2. As illustrated in FIG. 2, contaminant particles 202 are illustrated as having collected on a floor 204 of the loadlock chamber 200 over time, whereby the contaminant particles may accumulate and/or be transferred to the loadlock chamber to or from a workpiece 206 selectively positioned on a workpiece support 208 within a loadlock volume 210 of the loadlock chamber, or on other features within the loadlock chamber.

A vent gas source 212, for example, can comprise a high-pressure vent gas (e.g., nitrogen gas) that is selectively fluidly coupled to the loadlock chamber 200. It is to be appreciated that, should the vent gas source 212 quickly introduce the high-pressure vent gas to the loadlock chamber 200 at a high flow rate or a high pressure, such as described above, turbulent flow (illustrated as dashed lines 214) associated with the high flow rate and/or high pressure of the vent gas can disrupt or move the contaminant particles 202 within the loadlock chamber 200 and subsequently re-deposit the particles on the workpiece 206 when the workpiece is present within the loadlock chamber, thus potentially leading to defects.

The present disclosure appreciates that in an example when a maximum throughput through the ion implantation system 101 of FIG. 1 is desired, and where the implantation of ions into the workpiece 118 takes a minimal amount of time (e.g., 2-3 seconds), a fast venting of the loadlock chamber 200 of FIG. 2 can be advantageous for throughput, as the vent time (e.g., less than approximately 2 seconds) taken for venting of the loadlock chamber can be in the critical path, regardless of whether the workpiece 206 is present within the loadlock chamber. In such an instance, a fast venting of the loadlock chamber 200 can be desirable for throughput, regardless of a possibility of particle contamination of the workpiece 206, such that the time taken for venting of the loadlock chamber is minimized. In such an instance, the contaminant particles 202 can be removed through increased preventative maintenance of the loadlock chamber 200.

However, for longer processes performed on the workpiece 206, such as an ion implantation requiring an extended amount of time (e.g., 10-30 seconds or greater), the ion implantation process can be in the critical path, whereby the venting of the loadlock chamber 200 can advantageously comprise the aforementioned conditioning using higher pressures and/or higher flow rates associated with the venting of the loadlock chamber. However, such conditioning would be most advantageous when the workpiece 206 is not present within the loadlock chamber 200, and when such conditioning, itself, is not in the critical path of the process.

For example, in a process recipe requiring 30 seconds for the implantation of ions (called the “implant time”) into the workpiece 206 in the process chamber 122 of FIG. 1, when no workpiece is present in the loadlock chamber 200 of FIG. 2, venting pressure of the loadlock chamber can be advantageously increased to increase the flow and/or pressure of the vent gas introduced to the loadlock chamber, thus increasing the turbulent flow 214 and a likelihood of disturbing the contaminant particles 202 within the loadlock chamber for subsequent removal, thereof, while not affecting contamination of workpieces.

The implant time, for example, is associated with various attributes of the process recipe, such as a dosage of ions desired for the implant, a beam current of the ion beam 112 impacting the workpiece 118, as well as a scan velocity and a number of scans of the ion beam with respect to the workpiece, among other variables associated with the ion beam and/or process chamber 122. An initial implant time, for example, can be calculated or otherwise determined based on the attributes of the process recipe, whereby the initial implant time can be utilized to determine an initial vent pressure for conditioning the loadlock chamber 132. The initial vent pressure, for example, is determined such that the conditioning of the loadlock chamber 132 is not in the critical path of the process, whereby the initial vent pressure is maximized, and wherein a conditioning time during which the conditioning occurs is less than or equal to the initial implant time. The conditioning time, for example, can be a predetermined percentage of the initial implant time. Alternatively, the conditioning time can be determined by subtracting a predetermined buffer time from the initial implant time in order to ensure that the conditioning of the loadlock chamber 132 is not in the critical path.

The conditioning time, for example, can be utilized by a controller 216 to determine and provide a control one or more of a flow rate and a pressure of the vent gas provided from the vent gas source 212 to the loadlock chamber 200. Such a control of the flow rate and/or pressure of the vent gas from the vent gas source 212 thus controls the time taken for venting of the loadlock chamber 200 from the process pressure associated with the process environment 126 to approximately atmospheric pressure associated with the atmospheric environment 130. For example, the flow rate and/or pressure of the vent gas can be controlled by a vent gas control device 218 such as a mass flow controller, a pressure flow controller, a pressure regulator, a velocity regulator, a needle valve, or the like. A pressure sensor 220 can be further provided, whereby pressure feedback can be provided to the controller 216.

According to one example, a workpiece location system 222 is further associated with the loadlock chamber 200, wherein the workpiece location system 222 is configured to determine a presence of the workpiece 206 within the loadlock chamber. For example, the workpiece location system 222 may be configured to determine a presence of the workpiece 206 on the workpiece support 208 within the loadlock volume 210. The workpiece location system 222, for example, can comprise a workpiece sensor such as an optical sensor, proximity sensor, or other sensor configured to sense the workpiece 206 on the workpiece support 208 and to provide feedback to the controller 216 for providing selective control of the vent gas control device 218.

While the presence of the workpiece 206 on the workpiece support 208 can based on the sensing of the workpiece in the loadlock volume 210 of the loadlock chamber 200, in another example, the workpiece location system 222 can alternatively determine a presence of the workpiece in the loadlock chamber based on a processing time associated with processing the workpiece within the ion implantation system 101 of FIG. 1, and/or any otherwise known position of the workpiece throughout the ion implantation system. For example, the controller 160 of FIG. 1 can be further configured to determine the location of the workpiece 118 within the ion implantation system 101 based on the process recipe.

The controller 216 of FIG. 2, for example, is configured to consider the location of the workpiece 206 within the loadlock chamber 200 and to control a vent pressure setpoint to maximize the conditioning when the loadlock chamber is empty and has no workpiece 206 positioned therein. When the workpiece location system 222 determines that the workpiece 206 is present within the loadlock chamber 200, for example, the controller 216 is configured to lower the vent pressure setpoint so as to reduce the transfer of contaminant particles 202 onto the workpiece.

Accordingly, dynamic control of the vent gas control device can be achieved, whereby the position of the workpiece 206 within the loadlock chamber 200 can advantageously improve the effectiveness and timing of the above-described conditioning. For example, by providing a higher vent pressure and/or flow rate of the vent gas, fast vent times can be achieved when the workpiece is not present within the loadlock chamber 200. Since a higher vent pressure and/or flow rate is more effective at cleansing or conditioning the loadlock chamber 200, lower vent cycle times can be achieved, thus permitting either a greater number of vent/pump/vent cycles for a given time period, or for the conditioning routine to complete sooner. For example, if a conditioning routine associated with the loadlock chamber 132 of FIG. 1 is in the critical path of processing workpieces 118 through the ion implantation system 101, the above-described conditioning routine can permit a greater number of processed workpieces per day.

Conditioning of the loadlock chamber 132 can be thus performed between ion implantations of workpieces 118 in the process chamber 122. For example, the loadlock chamber 132 can be advantageously conditioned while a workpiece 118 is being implanted in the process chamber 122. The conditioning, in some examples, can include multiple pump/purge cycles between implants. Accordingly, the speed and flow rate associated with venting the loadlock chamber 132 to atmospheric pressure can be controlled to correlate the vent pressure and/or flow rate with the location of the workpiece 118.

For example, for long process times, such as for high current implants, the pressure or flow rate of the vent gas can be minimized or otherwise controlled to allow the loadlock chamber 200 to vent to atmospheric pressure at a slower rate, thus yielding a greater degree of a laminar flow 224, while at the same time, maintaining the vent time at less than the implantation time. As such, the process of venting of the loadlock chamber 200 is kept from being in the critical path of the process. Thus, there is less of a potential for dislodging, shifting, or otherwise disturbing the contaminant particles 202 within the loadlock chamber 200 by such a control of the pressure or flow rate of the vent gas associated with the venting to atmospheric pressure.

For short process times, such as for high energy implants, the pressure or flow rate of the vent gas can be maximized to keep the implantation process from being in the critical path, thus providing the desired throughput. Such a control of the pressure and flow rate of the vent gas in a process having a short implant time can still maximize the vent time. However, if throughput is the primary concern, the upper limit of the vent time can be approximately equal to the process time.

The present disclosure further appreciates that the vent pressure associated with conditioning of the loadlock chamber 132 can be further determined via a characterization of the workpiece processing system 100 of FIG. 1, such that various characteristics of the workpiece processing system can be utilized to maximize the vent pressure and/or flow rate while maintaining the desired throughput of workpieces 118 through the workpiece processing system. For example, characteristics such as the loadlock volume 150 of the loadlock chamber 132, flow or pressure capabilities of the vent gas control device 156, maximum speeds of transfer robots 142, 146, speeds of isolation valves or loadlock valves 136, 138, or other characteristics of other devices associated with the transport of workpieces 118 through the workpiece processing system 100 can be utilized to determine the maximum vent time to reduce particle contamination while maintaining the desired throughput. Such a characterization of the workpiece processing system 100 can be achieved mathematically (e.g., volumetric calculations associated with flow of the vent gas through the loadlock volume 150 of the loadlock chamber 132), or via a lookup table or other characterization scheme.

The present disclosure contemplates various process actions being performed in parallel with the venting of the loadlock chamber 132, such as the implantation process, as well as various workpiece transfer actions or other process actions. Workpiece transfer actions, for example, can comprise robotically transferring a workpiece 118 from the loadlock chamber 132 to the workpiece chuck 120 or other workpiece support apparatus (e.g., a heating station, cooling station, transfer station, etc.) within the process environment 126. Other example process actions can comprise workpiece alignment or workpiece presence verifications, as well as other pre-implantation or post-implantation actions. Accordingly, such process actions being performed in parallel with the venting of the loadlock chamber 132 can contribute to the determination of the vent pressure and/or flow rate and control of the pressure and/or flow rate of the vent gas into the loadlock chamber. For example, robotic transfer speeds can further contribute to the determination of the vent pressure to maximize the conditioning of the loadlock chamber 132 without the conditioning being in critical path of workpiece throughput.

Accordingly, the vent pressure and/or flow rate of the vent gas can be optimized based on the process time for any particular process. When throughput is the primary concern, the loadlock venting can be in the critical path. Thus, vent time can be minimized in order to minimize any impact of the loadlock venting being in the critical path of processing. When the loadlock venting is not in the critical path, however, the conditioning of the loadlock chamber can be maximized, while being less than or equal to the process time, such that pressures and/or flow rates of the vent gas can be advantageously increased to increase removal of particle contamination without deleteriously affecting throughput. Thus, the present disclosure provides a flexible control system that is applicable to many varied semiconductor processing systems having varied throughput limitations or requirements, while providing the ability to limit issues associated particle contamination.

Once one or more workpieces are processed through the processing system, either the same recipe and vent times, pressures, and/or flow rates can be utilized, or data associated with the processing system and vent times, pressures, and/or flow rates can be utilized as feedback for further determining subsequent vent times, pressures, and/or flow rates. Historical data (e.g., a lookup table) can be utilized to initially characterize the system, or the vent times, pressures, and/or flow rates can be calculated or other determined based on properties of the system, as discussed above. As such, the pressure and/or flow rate of the vent gas supplied to the loadlock chamber can be controlled based on the characterization or the feedback from the data associated with the processing system.

The present disclosure thus provides a balance of having optimal throughput while further providing optimal particle performance based on the optimal throughput. For example, the present disclosure contemplates instances where contaminant particles 202 are present in the loadlock chamber 132, where conventionally, such a presence of contaminant particles could be transferred to the workpiece due to the conventional venting routine. In order to mitigate such particle contamination in the past, the processing system would have been taken out of production for preventive maintenance, whereby the loadlock chamber would be opened to atmosphere, cleaned and wiped down, or otherwise maintained, thus losing productivity due to said maintenance.

However, in accordance with the present disclosure, when operating the workpiece processing system 100 having a process time that is greater than the conditioning time, the pressure and/or flow rate of the vent gas can be advantageously increased, whereby contaminant particles 202 that may exist within the loadlock chamber 132 can be pumped away, thus not transferring the contaminant particles to the workpiece 118 and requiring the additional preventive maintenance. By removing the contaminant particles 202 within the loadlock chamber 132 by the above-described conditioning, a time between preventive maintenance procedures can be extended, thus lowering the cost of ownership, and producing uptime benefits. Further, the time between preventive maintenance procedures can be modified based on particle performance.

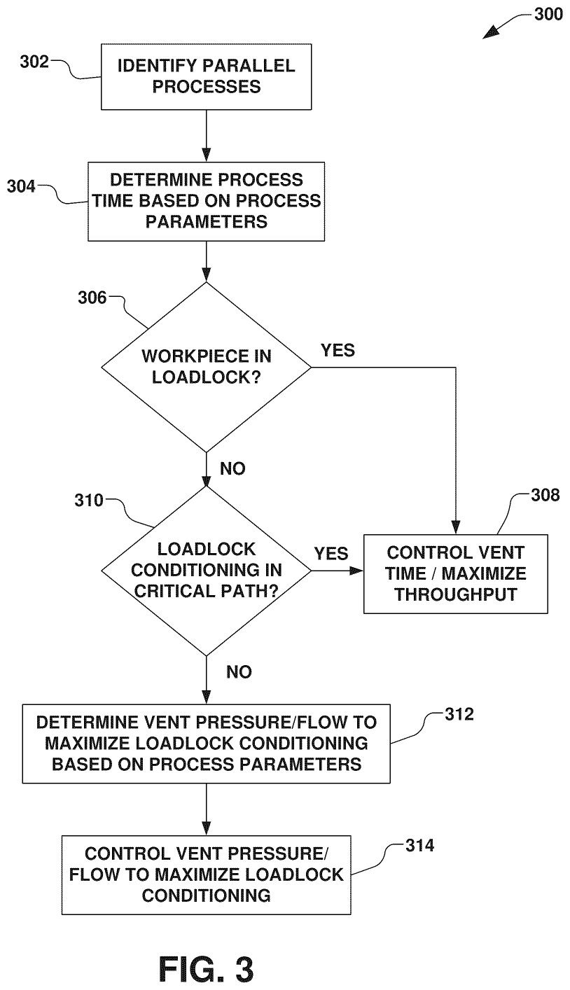

FIG. 3 illustrates an example methodology for optimizing vent times for various semiconductor processes. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 shown in FIG. 3, for example, begins with act 302, whereby parallel processes are identified in the workpiece processing system. The identification of parallel processes in act 302, for example, identifies potential critical paths in the process. For example, parallel processes of ion implantation and loadlock chamber venting and conditioning can be identified as being performed in parallel, whereby the process that takes a longer amount of time can be considered the critical path. Multiple processes, such as workpiece transfers, aligning processes, or workpiece verification processes may be further identified as being a parallel process, whereby each process may be considered individually, or grouped with other processes to determine potential critical paths of the process.

In act 304, a process time is determined, whereby the process time is based on process parameters associated with the workpiece processing system.

The process parameters, for example, can be a process recipe for processing of the workpiece, such as ion implantation parameters including desired beam current, implantation dose, number of scans of the ion beam, etc. Further, the process parameters may comprise a characterization of various components of the workpiece processing system, such as speeds of transferring workpieces, opening and closing of valves, cooling or heating times, or the like. Additionally, process parameters can comprise a desired process throughput based on capabilities of the workpiece processing system.

A determination is made in act 306 as to whether the workpiece is present in the loadlock chamber. If the determination in act 306 is such that there is a workpiece present in the loadlock chamber, the vent time is minimized or otherwise controlled in act 308 in order to maximize throughput of the workpieces through the system. For example, in act 308, the vent pressure and flow rate can be controlled or optimized to minimize the vent time while generally preventing a disturbing of contaminant particles within the loadlock chamber. If the determination in act 306 is such that there is no workpiece present in the loadlock chamber, however, a determination is made in act 310 as to whether the loadlock conditioning is in the critical path of processing of workpieces through the workpiece processing system. If the loadlock chamber conditioning process takes longer than the ion implantation process, for example, the loadlock chamber conditioning is considered to be in the critical path in act 310, and again, the vent time is controlled in act 308 in order to maximize throughput of the workpieces through the system, whereby in order to maximize throughput and minimize particle contamination, the vent pressure and/or flow rate is minimized.

If the determination made in act 310 is that the loadlock chamber conditioning is not in the critical path of the process, a determination of the vent pressure and/or flow of the vent gas for a maximum loadlock conditioning is made based on the process parameters in act 312. In act 314, the pressure and/or flow of the vent gas is controlled in accordance with the determination made in act 312, whereby the conditioning is maximized based, and particle contamination is minimized.

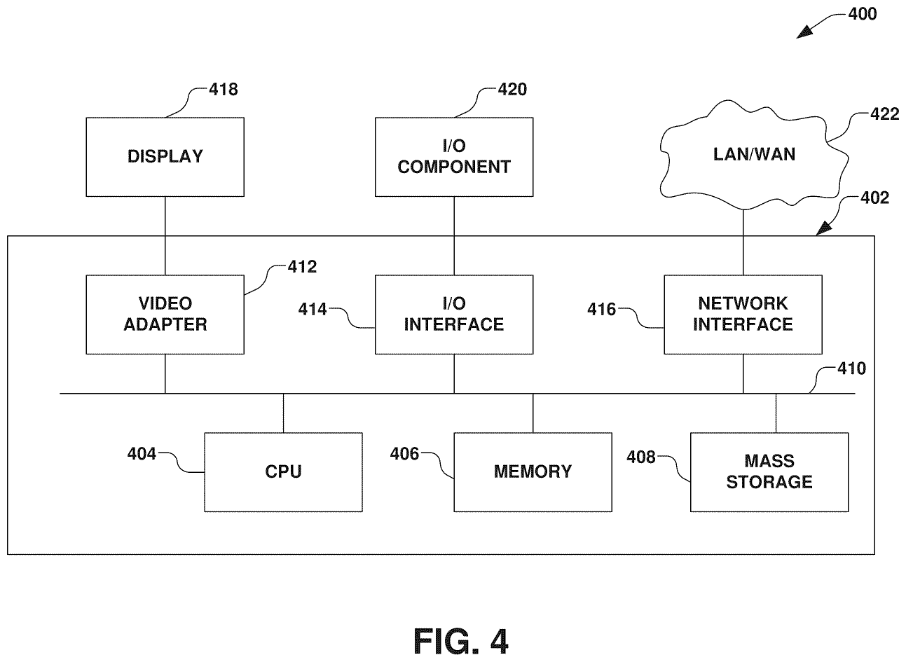

In accordance with another aspect, the aforementioned methodology may be implemented using computer program code in one or more of a controller, general purpose computer, or processor-based system. As illustrated in FIG. 4, a block diagram is provided of a processor-based system 400 in accordance with another embodiment. The processor-based system 400 is a general purpose computer platform and may be used to implement processes discussed herein. The processor-based system 400 may include a processing unit 402, such as a desktop computer, a workstation, a laptop computer, or a dedicated unit customized for a particular application. The processor-based system 400 may be equipped with a display 418 and one or more input/output devices 420, such as a mouse, a keyboard, or printer. The processing unit 402 may include a central processing unit (CPU) 404, memory 406, a mass storage device 408, a video adapter 412, and an I/O interface 414 connected to a bus 410.

The bus 410 may be one or more of any type of several bus architectures including a memory bus or memory controller, a peripheral bus, or video bus. The CPU 404 may include any type of electronic data processor, and the memory 406 may include any type of system memory, such as static random access memory (SRAM), dynamic random access memory (DRAM), or read-only memory (ROM).

The mass storage device 408 may include any type of storage device configured to store data, programs, and other information and to make the data, programs, and other information accessible via the bus 410. The mass storage device 408 may include, for example, one or more of a hard disk drive, a magnetic disk drive, or an optical disk drive.

The video adapter 412 and the I/O interface 414 provide interfaces to couple external input and output devices to the processing unit 402. Examples of input and output devices include the display 418 coupled to the video adapter 412 and the I/O device 420, such as a mouse, keyboard, printer, and the like, coupled to the I/O interface 414. Other devices may be coupled to the processing unit 402, and additional or fewer interface cards may be utilized. For example, a serial interface card (not shown) may be used to provide a serial interface for a printer. The processing unit 402 also may include a network interface 416 that may be a wired link to a local area network (LAN) or a wide area network (WAN) 422 and/or a wireless link.

It should be noted that the processor-based system 400 may include other components. For example, the processor-based system 400 may include power supplies, cables, a motherboard, removable storage media, cases, and the like. These other components, although not shown, are considered part of the processor-based system 400.

Embodiments of the present disclosure may be implemented on the processor-based system 400, such as by program code executed by the CPU 404. Various methods according to the above-described embodiments may be implemented by program code. Accordingly, explicit discussion herein is omitted.

Further, it should be noted that various modules and devices in FIGS. 1-3 may be implemented on and controlled by one or more processor-based systems 400 of FIG. 4. Communication between the different modules and devices may vary depending upon how the modules are implemented. If the modules are implemented on one processor-based system 400, data may be saved in memory 406 or mass storage device 408 between the execution of program code for different steps by the CPU 404. The data may then be provided by the CPU 404 accessing the memory 406 or mass storage device 408 via bus 410 during the execution of a respective step. If modules are implemented on different processor-based systems 400 or if data is to be provided from another storage system, such as a separate database, data can be provided between the systems 400 through I/O interface 414 or network interface 416. Similarly, data provided by the devices or stages may be input into one or more processor-based system 400 by the I/O interface 414 or network interface 416. A person having ordinary skill in the art will readily understand other variations and modifications in implementing systems and methods that are contemplated within the scope of varying embodiments.

Although the disclosure has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplified embodiments of the disclosure. In addition, while a particular feature of the disclosure may have been disclosed with respect to only one of several embodiments, such feature may be combined with one or more other features of the other embodiments as may be desired and advantageous for any given or particular application.

What is claimed is:

1. A workpiece processing system comprising:
a process chamber configured for processing a workpiece within a process environment at a vacuum pressure, whereby processing the workpiece defines a process time;
a loadlock chamber defining a loadlock volume therein, wherein the loadlock chamber comprises:
a workpiece support configured to selectively support the workpiece within the loadlock volume;
a vacuum isolation valve configured to provide selective fluid communication between the loadlock volume and the process environment, wherein the vacuum isolation valve is further configured to selectively permit the workpiece to transfer between a loadlock position within the loadlock volume and the process environment; and
an atmospheric isolation valve configured to provide selective fluid communication between the loadlock volume and an atmospheric environment at an atmospheric pressure, wherein the atmospheric isolation valve is further configured to selectively permit the workpiece to transfer between the loadlock position and the atmospheric environment;
a vent gas control device configured to selectively control one or more of a pressure and a flow rate of a vent gas from a vent gas source to the loadlock volume, wherein a vent time is defined by a change from the vacuum pressure to the atmospheric pressure within the loadlock volume;
a workpiece location system configured to determine a presence of the workpiece on the workpiece support within the loadlock volume; and
a controller configured to control the vent gas control device based, at least in part, on the presence of the workpiece on the workpiece support, the process time, and the vent time, wherein the controller is configured to maximize the one or more of the pressure and the flow rate of the vent gas from the vent gas source to the loadlock chamber when the workpiece is not present on the workpiece support, thereby maximizing a conditioning of the loadlock chamber.

2. The workpiece processing system of claim 1, further comprising a pressure monitor configured to measure a loadlock pressure within the loadlock volume, and wherein the controller is further configured to control the vent gas control device based on the loadlock pressure.

3. The workpiece processing system of claim 1, wherein the controller is further configured to control the vent gas control device based on a plurality of process parameters associated with the process chamber and the loadlock chamber.

4. The workpiece processing system of claim 3, wherein the plurality of process parameters comprise one or more of a process recipe associated with processing the workpiece within the process environment and a characterization of the loadlock chamber, wherein the characterization of the loadlock chamber defines a minimum vent time.

5. The workpiece processing system of claim 4, further comprising an ion implantation system configured to process the workpiece by directing an ion beam toward the workpiece within the process chamber.

6. The workpiece processing system of claim 1, further comprising a vacuum control device configured to selectively evacuate the loadlock volume and to control the vacuum pressure from a vacuum source to the loadlock volume, wherein a vacuum time is defined by a change from the atmospheric pressure to the vacuum pressure within the loadlock volume.

7. The workpiece processing system of claim 1, wherein the workpiece location system comprises a workpiece sensor configured to sense the workpiece on the workpiece support and to provide feedback to the controller.

8. The workpiece processing system of claim 7, wherein the workpiece sensor comprises one or more of an optical sensor and a proximity sensor configured to detect the workpiece when the workpiece is present on the workpiece support.

9. The workpiece processing system of claim 1, wherein the controller is further configured determine the presence of the workpiece on the workpiece support.

10. The workpiece processing system of claim 1, wherein the vent gas control device comprises one of a mass flow controller, a pressure flow controller, a pressure regulator, a velocity regulator, and a needle valve.

11. The workpiece processing system of claim 1, wherein the controller is configured to maximize the flow rate concurrent with the change from the vacuum pressure to the atmospheric pressure.

12. A workpiece processing system comprising:
a process chamber configured for processing a workpiece within a process environment at a vacuum pressure;
a loadlock chamber defining a loadlock volume and having a workpiece support disposed therein, wherein the workpiece support is configured to selectively support the workpiece in a loadlock environment, and wherein the loadlock chamber is configured to selectively isolate the process environment from an atmospheric environment at atmospheric pressure;
a vent gas control device configured to selectively control one or more of a pressure and a flow rate of a vent gas from a vent gas source to the loadlock volume, wherein a vent time is defined by a change from the vacuum pressure to the atmospheric pressure within the loadlock volume;
a workpiece location system configured to determine a presence of the workpiece on the workpiece support within the loadlock volume; and
a controller configured to control the vent gas control device based, at least in part, on the presence of the workpiece on the workpiece support, wherein the controller is configured to maximize the one or more of the pressure and the flow rate of the vent gas from the vent gas source to the loadlock chamber within the vent time when the workpiece is not present on the workpiece support, thereby maximizing a conditioning of the loadlock chamber.

13. The workpiece processing system of claim 12, wherein the loadlock chamber further comprises:
a vacuum isolation valve configured to provide selective fluid communication between the loadlock volume and the process environment, wherein the vacuum isolation valve is further configured to selectively permit the workpiece to transfer between the workpiece support and the process environment; and
an atmospheric isolation valve configured to provide selective fluid communication between the loadlock volume and the atmospheric environment, wherein the atmospheric isolation valve is further configured to selectively permit the workpiece to transfer between the workpiece support and the atmospheric environment.

14. The workpiece processing system of claim 12, wherein processing the workpiece within the process chamber defines a process time, and wherein the controller is further configured to control the vent gas control device based on the process time.

15. The workpiece processing system of claim 12, further comprising a pressure monitor configured to measure a loadlock pressure within the loadlock volume, and wherein the controller is further configured to control the vent gas control device based on the loadlock pressure.

16. The workpiece processing system of claim 12, wherein the controller is further configured to control the vent gas control device based on a plurality of process parameters associated with the process chamber and the loadlock chamber.

17. The workpiece processing system of claim 16, wherein the plurality of process parameters comprise one or more of a process recipe associated with processing the workpiece within the process environment and a characterization of the loadlock chamber, wherein the characterization of the loadlock chamber defines a minimum vent time.

18. The workpiece processing system of claim 12, wherein the workpiece location system comprises a workpiece sensor configured to sense the workpiece on the workpiece support and to provide feedback to the controller, and wherein the workpiece sensor comprises one or more of an optical sensor and a proximity sensor configured to detect the workpiece when the workpiece is present on the workpiece support.

19. The workpiece processing system of claim 12, wherein the vent gas control device comprises one of a mass flow controller, a pressure flow controller, a pressure regulator, a velocity regulator, a needle valve.

20. A method for conditioning a loadlock chamber in a workpiece processing system, the method comprising:
identifying parallel processes in the workpiece processing system, thereby defining a critical path associated with processing a workpiece;
determining a process time based on process parameters associated with the workpiece processing system;
determining a presence of the workpiece in the loadlock chamber;
determining whether a venting of the loadlock chamber is in the critical path;
maximizing a throughput of the workpiece through the workpiece processing system if the workpiece present in the loadlock chamber or if the venting of the loadlock chamber is in the critical path; and
maximizing one or more of a vent pressure and a flow rate of a vent gas to the loadlock chamber when the workpiece is not present in the loadlock chamber, whereby the one or more of the vent pressure and the flow rate are further maximized based on the process parameters, thereby maximizing a conditioning of the loadlock chamber.
